(19) United States
(12) Patent Application Publication
(10) Pub. No.: US 2014/0008756 A1
(43) Pub. Date: Jan. 9, 2014

(54) DEEP TRENCH HEAT SINK

(71) Applicants: Chengwen Pei, Danbury, CT (US); Gan Wang, Fishkill, NY (US)

(72) Inventors: Chengwen Pei, Danbury, CT (US); Gan Wang, Fishkill, NY (US)

(73) Assignee: INTERNATIONAL BUSINESS MACHINES CORPORATION, ARMONK, NY (US)

(21) Appl. No.: 13/543,966

(22) Filed: Jul. 9, 2012

(51) Int. Cl. H01L 21/306; H01L 23/34

(52) U.S. Cl. 257/506; 438/584; 257/E21.215; 257/E23.08

(57) ABSTRACT

A method including providing a silicon-on-insulator (SOI) substrate including a SOI layer, a buried oxide layer, and a base layer; the buried oxide layer is located below the SOI layer and above the base layer, and the buried oxide layer insulates the SOI layer from the base layer; etching a deep trench into the SOI substrate, the deep trench having a sidewall and a bottom, the deep trench extends from a top surface of the SOI layer, through the buried oxide layer, down to a location within the base layer; forming a dielectric liner on the sidewall and the bottom of the deep trench; forming a conductive fill material on top of the dielectric liner and substantially filling the deep trench, the fill material being thermally conductive; and transferring heat from the SOI layer to the base layer via the fill material.

### BACKGROUND

1. Field of the Invention

The present invention relates generally to semiconductors, and, more particularly, to deep trench heat sinks.

2. Background of Invention

As integrated circuits on semiconductor chips become denser, faster and more complex, their electrical performance requirements become higher and the need for dissipating heat becomes greater. Consequently, the problem may be complicated by the prevalent use of silicon-on-insulator substrates because an insulating layer may be known to prevent the transfer of heat into the entire substrate thereby trapping immense heat in a device layer. Therefore, integrated circuits built using SOI substrates may benefit from a greater and more effective method of removing heat from the device layer.

### SUMMARY

According to one embodiment of the present invention, a method is provided. The method may include providing a silicon-on-insulator (SOI) substrate including a SOI layer, a buried oxide layer, and a base layer; the buried oxide layer is located below the SOI layer and above the base layer, and the buried oxide layer insulates the SOI layer from the base layer; etching a deep trench into the SOI substrate, the deep trench having a sidewall and a bottom, the deep trench extends from a top surface of the SOI layer, through the buried oxide layer, down to a location within the base layer; forming a dielectric liner on the sidewall and the bottom of the deep trench; forming a conductive fill material on top of the dielectric liner and substantially filling the deep trench, the fill material being thermally conductive; and transferring heat from the SOI layer to the base layer via the fill material.

According to another exemplary embodiment of the present invention, a structure is provided. The structure may include a silicon-on-insulator (SOI) substrate including a SOI layer, a buried oxide layer, and a base layer; the buried oxide layer is located below the SOI layer and above the base layer, and the buried oxide layer insulates the SOI layer from the base layer; a deep trench extending into the SOI layer from a top surface of the SOI layer, through the buried oxide layer, down to a location within the base layer, the deep trench having a sidewall and a bottom; a dielectric liner located along the sidewall and the bottom of the deep trench; a conductive fill material located on top of the dielectric liner and substantially filling the deep trench, the fill material being thermally conductive.

### BRIEF DESCRIPTION OF THE SEVERAL VIEWS OF THE DRAWINGS

The following detailed description, given by way of example and not intend to limit the invention solely thereto, will best be appreciated in conjunction with the accompanying drawings, in which:

FIGS. 1A-1D illustrate the steps of a method of forming a deep trench heat sink.

FIG. 1A depicts the formation of a deep trench in a silicon-on-insulator (SOI) substrate according to an exemplary embodiment.

FIG. 1B depicts the formation of a dielectric liner within the deep trench according to an exemplary embodiment.

FIG. 1C depicts the formation of a first conductive layer on top of the dielectric liner according to an exemplary embodiment.

FIG. 1D depicts the formation of a second conductive layer on top of the first conductive layer, and the final deep trench heat sink structure according to an exemplary embodiment.

FIG. 2 depicts a deep trench heat sink structure situated in close proximity to a semiconductor device formed on the SOI substrate according to an exemplary embodiment.

FIG. 3 depicts a deep trench heat sink according to an exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiment set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

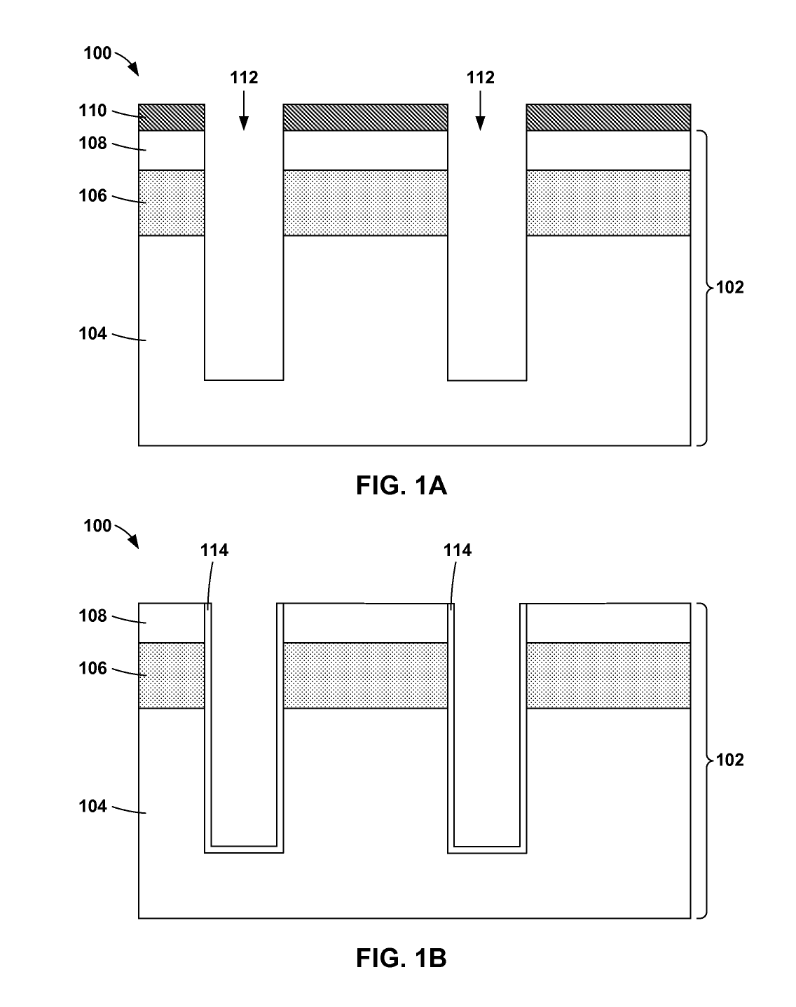

Referring now to FIGS. 1A-1D exemplary process steps of forming a deep trench heat sink in accordance with one embodiment of the present invention are shown. Specifically, a deep trench may first be etched into an SOI substrate using conventional processes known in the art. Next, an insulating liner may be deposited within the deep trench. The deep trench may then be filled with one or more thermally conductive materials. The deep trench heat sink may be designed to efficiently and effectively transfer heat from a device layer to a base layer via the deep trench heat sink. It should be noted that while reference is made to a single deep trench heat sink, multiple deep trench heat sinks are depicted in the drawings and a single semiconductor structure may include multiple deep trench heat sinks. Below is a detail description of the deep trench heat sink.

Referring now to FIG. 1A, a deep trench 112 may be formed in a silicon-on-insulator substrate 102. The SOI substrate 102 may include a base layer 104, a buried oxide (BOX) layer 106 formed on top of the base layer 104, and a SOI layer 108 formed on top of the BOX layer 106. The BOX layer 106 isolates the SOI layer 108 from the base layer 104. The base layer 104 may be made from any of several known semiconductor materials such as, for example, a bulk silicon substrate. Other non-limiting examples include silicon, germanium, silicon-germanium alloy, silicon carbide, silicon-germanium carbide alloy, and compound semiconductor materials. Non-limiting examples of compound semiconductor materials include gallium arsenide, indium arsenide, and indium phosphide. Typically, the base layer 104 may be about, but is not limited to, several hundred microns thick. For example, the base layer 104 may include a thickness ranging from 0.5 mm to about 1.5 mm.

The BOX layer 106 may be formed from any of several dielectric materials known in the art. Non-limiting examples include, for example, oxides, nitrides, and oxynitrides of silicon. Oxides, nitrides and oxynitrides of other elements are also envisioned. In addition, the BOX layer 106 may include crystalline or non-crystalline dielectric material. Moreover, the BOX layer 106 may be formed using any of several known methods. Non-limiting examples include ion implantation methods, thermal or plasma oxidation or nitridation methods, chemical vapor deposition methods and physical vapor deposition methods. In one embodiment, the BOX layer 106 may be about 150 nm thick. Alternatively, the BOX layer 106 may include a thickness ranging from about 10 nm to about 500 nm.

The SOI layer 108 may include any of the several semiconductor materials included in the base layer 104. In general, the base layer 104 and the SOI layer 108 may include either identical or different semiconducting materials with respect to chemical composition, dopant concentration, and crystallographic orientation. In one embodiment of the present invention, the base layer 104 and the SOI layer 108 may include semiconducting materials that include at least different crystallographic orientations.

Typically the base layer 104 or the SOI layer 108 include a {101} crystallographic orientation and the other of the base layer 104 or the SOI layer 108 includes a {100} crystallographic orientation. Typically, the SOI layer 108 includes a thickness ranging from about 5 nm to about 100 nm. Methods for making the SOI layer 108 are well known in the art. Non-limiting examples include SIMOX (Separation by Implantation of Oxygen), wafer bonding, and ELTRAN® (Epitaxial Layer TRANsfer).

With continued reference to FIG. 1A, a cell location is identified and a mask layer 110 of a suitable masking material may be deposited on the SOI layer 108 and patterned using a conventional photolithographic techniques. The mask layer 110 may include suitable masking materials such as, for example, photoresist or hardmask such as silicon dioxide. The deep trench 112 may be formed by etching into, but not through, the SOI substrate 102. The deep trench 112 can be formed using, for example, an anisotropic dry etch technique, such as reactive ion etching (RIE). The mask layer 110 may be removed after the deep trench 112 is formed or, alternatively, in a subsequent process. The deep trench 112 may have an aspect ratio ranging from, but not limited to, about 30 to about 50. The deep trench 112 may have a width ranging from about 50 nm to about 500 nm and a depth (height) ranging from about 1 μm to about 6 μm. In one embodiment, the deep trench 112 may have a width ranging from about 60 nm to about 200 nm and a depth (height) ranging from about 3 μm to about 5 μm.

Referring now to FIG. 1B, a dielectric liner 114 can be formed within the deep trench 112 (show in FIG. 1A) by any suitable process such as thermal oxidation, thermal nitridation, atomic layer deposition (ALD), chemical vapor deposition (CVD), and the like. The dielectric liner 114 may have a thickness ranging from about 3 nm to 20 nm, although a thickness of the dielectric liner 114 less than 3 nm or greater than 20 nm may be conceived. The dielectric liner may include, for example, oxide, nitride, oxynitride or high-k materials. In one embodiment, the dielectric liner 114 may include HfSiOₓ deposited by ALD. In one embodiment, the dielectric liner 114 may include HfOₓ deposited by ALD. The dielectric liner 114 may serve as an electrical barrier to maintain the electrical isolation between active devices and the deep trench heat sinks, and maintain the electrical isolation between the base layer 104 and the SOI layer 108 provided by the BOX layer 106.

Referring now to FIG. 1C, a first conductive layer 116 may then be deposited on top of the dielectric liner 114. The first conductive layer 116 may have a thickness ranging from about 2 nm to 10 nm, although a thickness of the first conductive layer 116 less than 2 nm or greater than 10 nm may be conceived.

The first conductive layer 116 may include any suitable conductive material, including but not limited to, doped polycrystalline or amorphous silicon, germanium, silicon germanium, a metal, a conducting metallic compound material, carbon nanotube, conductive carbon, or any suitable combination of these materials. Examples of metals may include tungsten, titanium, tantalum, ruthenium, and zirconium. Examples of conducting metallic compounds may include tantalum nitride, titanium nitride, tungsten silicide, tungsten nitride, titanium nitride, and tantalum nitride. In one embodiment, the first conductive layer 116 may include any material known in the art to have enhanced thermal conductivity properties, such as, for example, tungsten, titanium, and titanium nitride.

The first conductive layer 116 can be deposited by any suitable methods, including but not limited to, atomic layer deposition (ALD), chemical vapor deposition (CVD), low-pressure chemical vapor deposition (LPCVD), ultrahigh vacuum chemical vapor deposition (UHVCVD), metalorganic chemical vapor deposition (MOCVD), physical vapor deposition, sputtering, plating, evaporation, spin-on-coating, ion beam deposition, electron beam deposition, laser assisted deposition, and chemical solution deposition. In one particular embodiment, the first conductive layer 116 may include doped polysilicon deposited by LPCVD.

Referring now to FIG. 1D, a second conductive layer 118 may be deposited on top of the first conductive layer 116 and fill any remaining opening in the deep trench 112 (shown in FIG. 1A). The second conductive layer 118 may have a thickness ranging from about 5 nm to 50 nm, although a thickness of the second conductive layer 118 less than 5 nm or greater than 50 nm may be conceived. The second conductive layer 118 may include any suitable conductive material, including but not limited to, doped polycrystalline or amorphous silicon, germanium, silicon germanium, a metal, a conducting metallic compound material, carbon nanotube, conductive carbon, or any suitable combination of these materials. Examples of metals may include tungsten, titanium, tantalum, ruthenium, and zirconium. Examples of conducting metallic compounds may include tantalum nitride, titanium nitride, tungsten silicide, tungsten nitride, titanium nitride, and tantalum nitride. In one embodiment, the second conductive layer 118 may include any material known in the art to have enhanced thermal conductivity properties, such as, for example, doped or undoped polycrystalline, amorphous silicon, and amorphous carbon.

The second conductive layer 118 can be deposited by any suitable methods, including but not limited to, atomic layer deposition (ALD), chemical vapor deposition (CVD), low-pressure chemical vapor deposition (LPCVD), ultrahigh vacuum chemical vapor deposition (UHVCVD), metalorganic chemical vapor deposition (MOCVD), physical vapor deposition, sputtering, plating, evaporation, spin-on-coating, ion beam deposition, electron beam deposition, laser assisted deposition, and chemical solution deposition. In one particular embodiment, the second conductive layer 110 may include doped polysilicon deposited by LPCVD.

The arrangement of the dielectric liner 114, the first conductive layer 116, and the second conductive layer 118 described above and shown in FIG. 1D forms a deep trench heat sink 120. The deep trench heat sink 120 may be designed to transfer heat from the SOI layer 108 to the base layer 104 via the conductive layers 116, 118 of the deep trench. The first and second conductive layers 116, 118 may be made from the same material or different materials, but both may be thermally conductive.

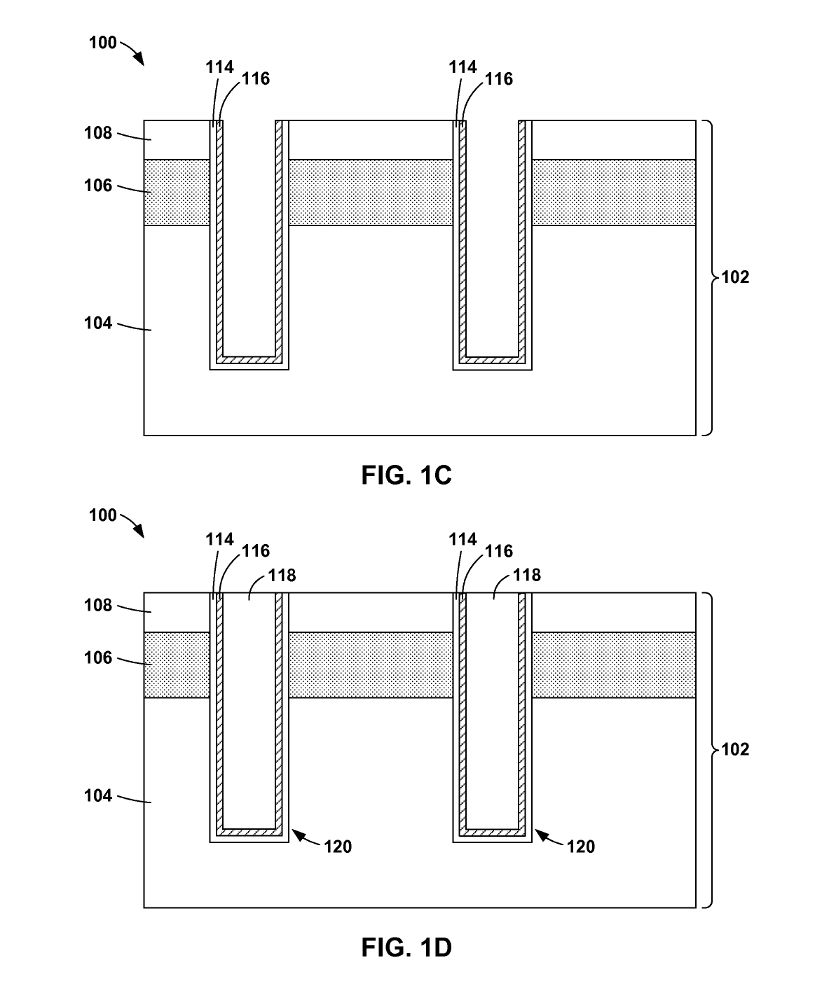

Referring now to FIG. 2, a structure 200 is shown having a deep trench heat sink 120 situated near a semiconductor device 224. The semiconductor device 224 may include, but is not limited to, for example, a field effect transistor. Generally, heat generated by semiconductor devices formed on bulk substrates, as opposed to SOI substrates, may be dissipated throughout the bulk substrate. In turn, heat generated by the semiconductor device 224, formed on the SOI substrate 102, may be trapped in the SOI layer 108 because of the BOX layer 106. The BOX layer 106 may act as a thermal insulator preventing heat from dissipating throughout the entire SOI substrate 102. This problem is compounded by the fact that the SOI layer 108 is generally very thin, on the order of 50 nm to 100 nm thick. As in typical semiconductor construction, multiple shallow trench isolation (STI) regions 222 may be placed between devices to electrically insulate one semiconductor device from another.

The deep trench heat sink 120 may not be in electrical connection with the semiconductor device 224, but rather the deep trench heat sink should be electrically insulated from the semiconductor device 224. Therefore, the deep trench heat sink 120 may be located in close proximity to the semiconductor device 224. It should be noted that the deep trench heat sink 120 may function as a heat sink and continue to transfer heat from the SOI layer 108 to the base layer 104 regardless of its positioning relative to the semiconductor device 224. However, because the semiconductor device 224 may be a primary source of heat, the deep trench heat sink 120 may be more effective the closer it is positioned to the semiconductor device 224.

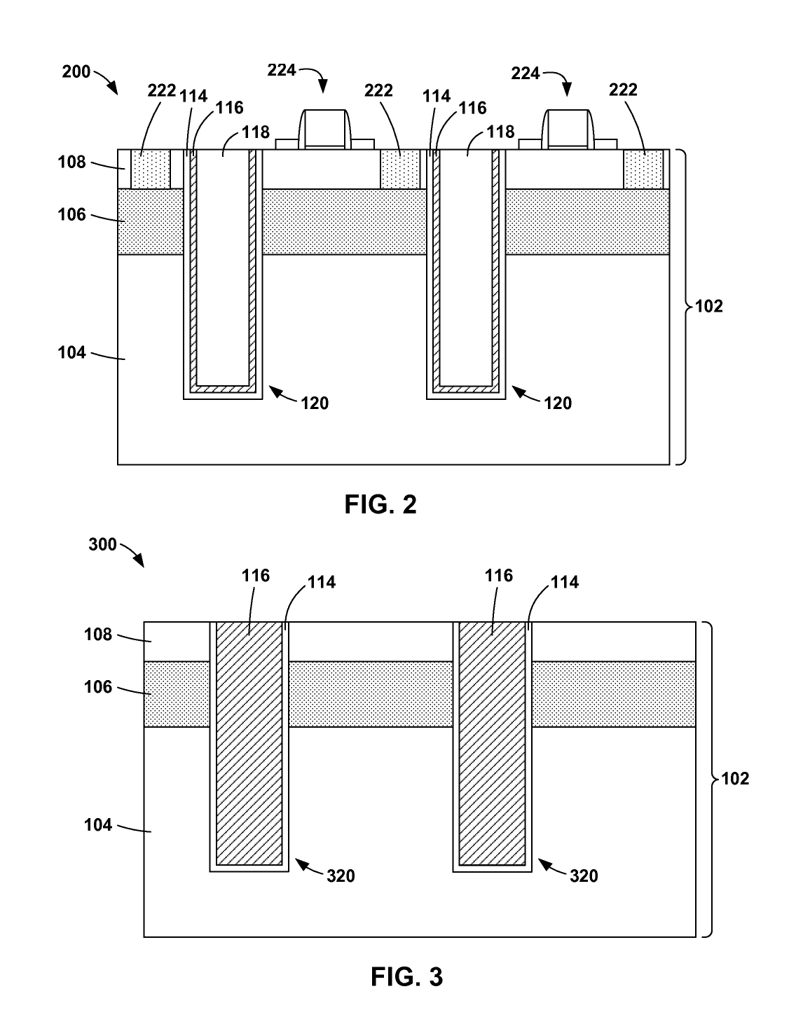

Referring now to FIG. 3, in one embodiment a structure 300 is shown having the deep trench heat sink 320. The deep trench heat sink 320 in this embodiment includes the dielectric liner 114 and the first conductive layer 116. The first conductive layer 116 may be deposited on top of the dielectric liner 114 and fill the deep trench. In contrast to the deep trench heat sink 120 in FIG. 2, the deep trench heat sink 320 does not have the second conductive layer 118 (shown in FIG. 1D) Like the deep trench heat sink 120 of FIG. 2, the deep trench heat sink 320 may be positioned in close proximity to a semiconductor device.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein.

What is claimed is:

1. A method comprising:
providing a silicon-on-insulator (SOI) substrate comprising a SOI layer, a buried oxide layer, and a base layer; wherein the buried oxide layer is located below the SOI layer and above the base layer, and wherein the buried oxide layer insulates the SOI layer from the base layer;
etching a deep trench into the SOI substrate, the deep trench having a sidewall and a bottom, wherein the deep trench extends from a top surface of the SOI layer, through the buried oxide layer, down to a location within the base layer;
forming a dielectric liner on the sidewall and the bottom of the deep trench;
forming a conductive fill material on top of the dielectric liner and substantially filling the deep trench, the fill material being thermally conductive; and
transferring heat from the SOI layer to the base layer via the fill material.

2. The method of claim 1, further comprising:
forming a conductive liner between the dielectric liner and the fill material; and
transferring heat from the SOI layer to the base layer via the conductive liner.

3. The method of claim 2, wherein the conductive liner comprises a material selected from the group consisting of: polycrystalline, silicon, amorphous silicon, germanium, silicon germanium, metals, conducting metallic compound materials, carbon nanotube, and conductive carbon.

4. The method of claim 2, wherein the conductive liner comprises a material selected from the group consisting of: tungsten, titanium, and titanium nitride.

5. The method of claim 1, wherein the dielectric liner comprises a material selected from the group consisting of: oxide, nitride, oxynitride, and high-k dielectric.

6. The method of claim 1, wherein the dielectric liner comprises a material selected from the group consisting of: HfSiOₓ and HfOₓ.

7. The method of claim 1, wherein the fill material comprises a material selected from the group consisting of: polycrystalline, silicon, amorphous silicon, germanium, silicon germanium, metals, conducting metallic compound materials, carbon nanotube, and conductive carbon.

8. The method of claim 1, wherein the fill material comprises a material selected from the group consisting of: tungsten, titanium, and titanium nitride.

9. The method of claim 1, wherein the conductive fill material is thermally conductive.

10. The method of claim 1, wherein the depositing the dielectric liner comprises depositing a material ranging in thickness from 3 nm to 20 nm.

11. The method of claim 1, wherein the deep trench is located adjacent to a semiconductor device, and wherein the semiconductor device remains electrically insulated from the deep trench.

12. The method of claim 1, wherein the deep trench has a vertical depth ranging from about 1 μm to about 6 μm, and a width ranging from about 50 nm to about 500 nm.

13. A structure comprising:
a silicon-on-insulator (SOI) substrate comprising a SOI layer, a buried oxide layer, and a base layer; wherein the buried oxide layer is located below the SOI layer and above the base layer, and wherein the buried oxide layer insulates the SOI layer from the base layer;
a deep trench extending into the SOI layer from a top surface of the SOI layer, through the buried oxide layer, down to a location within the base layer, the deep trench having a sidewall and a bottom;
a dielectric liner located along the sidewall and the bottom of the deep trench;
a conductive fill material located on top of the dielectric liner and substantially filling the deep trench, the fill material being thermally conductive.

14. The structure of claim 13, further comprising:
a conductive liner located between the dielectric liner and the fill material.

15. The structure of claim 14, wherein the conductive liner comprises a material selected from the group consisting of: tungsten, titanium, and titanium nitride.

16. The structure of claim 13, wherein the dielectric liner comprises a material selected from the group consisting of: oxide, nitride, oxynitride, and high-k dielectric.

17. The structure of claim 13, wherein the fill material comprises a material selected from the group consisting of: polycrystalline, silicon, amorphous silicon, germanium, silicon germanium, metals, conducting metallic compound materials, carbon nanotube, and conductive carbon.

18. The structure of claim 13, wherein the deep trench is located adjacent to a semiconductor device, and wherein the semiconductor device remains electrically insulated from the deep trench.

19. The structure of claim 13, wherein the deep trench has a vertical depth ranging from about 1 μm to about 6 μm, and a width ranging from about 50 nm to about 500 nm.
